(19) United States
(12) Patent Application Publication
(10) Pub. No.: US 2023/0339985 A1
(43) Pub. Date: Oct. 26, 2023

(54) Organometallic Compound For Thin Film Deposition And Method For Forming Group 4 Metal-Containing Thin Film Using Same

(71) Applicant: EGTM Co., Ltd., Suwon-Si (KR)

(72) Inventors: Sung Jun JI, Suwon-Si (KR); Kyuho CHO, Suwon-Si (KR); Sun Young BAIK, Incheon (KR); Ju Hwan JEONG, Yongin-Si (KR); Tae Young LEE, Suwon-Si (KR); Shin Beom KIM, Seongnam-Si (KR); Woong Jin CHOI, Suwon-Si (KR)

(21) Appl. No.: 18/135,413

(22) Filed: Apr. 17, 2023

(30) Foreign Application Priority Data
Apr. 25, 2022 (KR) 10-2022-0050896

(51) Int. Cl. C07F 7/00; C23C 16/18; C23C 16/455; C23C 16/52

(52) U.S. Cl. CPC C07F 7/00; C23C 16/18; C23C 16/45527; C23C 16/52

(57) ABSTRACT

According to examples of the present disclosure, the organometallic compound is represented by Formula 1 below, which is used as a precursor when a Group 4 metal-containing thin film is deposited to provide a high-quality Group 4 metal-containing thin film.

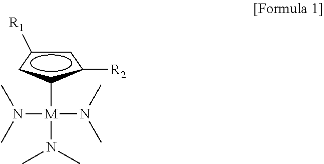

In Formula 1, M is Zr or Hf, R1 is selected from a linear alkyl group having 2 to 6 carbon atoms and a branched alkyl group having 3 to 6 carbon atoms, R2 is a linear alkyl group having 1 to 3 carbon atoms, and R1 and R2 are different from each other.

### CROSS-REFERENCE TO RELATED APPLICATIONS

This application claims the priority of Korean Patent Application No. 10-2022-0050896 filed on Apr. 25, 2022, in the Korean Intellectual Property Office, the disclosure of which is incorporated herein by reference.

### BACKGROUND

### Field

The present disclosure relates to a Group 4 organometallic compound and a method for forming a Group 4 metal-containing thin film using the same, and more particularly, to a Group 4 organometallic compound which is used as a precursor for thin film deposition and has improved thermal stability, and a method for forming a Group 4 metal-containing thin film using the same.

### Description of the Related Art

Due to the development of electronic technology, demands for miniaturization and weight reduction of electronic elements used in various electronic devices are rapidly increasing. Accordingly, various physical and chemical deposition methods for forming miniaturized electronic elements have been proposed. Research for forming various types of metal thin films, such as metal thin films, metal oxide thin films, and metal nitride thin films, by such deposition methods, and manufacturing various semiconductor elements therefrom, is being actively conducted. In the manufacture of semiconductor elements, metal-containing thin films are generally formed using a metal organic chemical vapor deposition (MOCVD) or atomic layer deposition (ALD) process. Since the ALD process performs a self-limiting reaction, step coverage is superior to that of the MOCVD process, and since the ALD process is a relatively low-temperature process, it has an advantage of avoiding deterioration of element characteristics due to thermal diffusion.

In order to form a high-quality metal-containing thin film through the MOCVD or ALD process, a precursor compound should have a high vapor pressure at low temperatures so that it can be easily delivered to the reaction chamber without being decomposed during heating for vaporization. In addition, it is preferable that the precursor compound is thermally sufficiently stable so that it can be used in a wide deposition temperature range from a low temperature to a high temperature, and has a low viscosity liquid state to facilitate handling and deposition process.

Meanwhile, tris(dimethylamino)cyclopentadienyl zirconium(IV) [CpZr(NMe₂)₃], a well-known Group 4 organometallic precursor, is a liquid at room temperature and has a high vapor pressure. However, this has had problems in that the deposition process temperature is limited and side reactants are produced during the deposition process. Accordingly, there has been a problem in that the step coverage is low even though the ALD process, which is a deposition method with relatively excellent step coverage, is used. In addition, due to poor thermal stability, thermal decomposition occurred during deposition, making it difficult to form a high-quality zirconium thin film.

### SUMMARY

An object of the present disclosure is to provide a Group 4 organometallic compound that is liquid at room temperature, has a high vapor pressure at low temperatures so that it has an advantage of facilitating handling and deposition process, and enables high-quality metal-containing thin films to be formed.

Further, another object of the present disclosure is to provide a precursor composition for thin film deposition capable of forming a high-quality Group 4 metal-containing thin film having uniform film quality and high density using the organometallic compound and a method for forming a Group 4 metal-containing thin film using the same.

The tasks of the present disclosure are not limited to the tasks mentioned above, and other tasks not mentioned will be clearly understood by those skilled in the art from the following description.

An organometallic compound according to one example of the present disclosure may be represented by Formula 1.

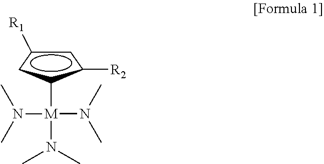

In Formula 1, M is Zr or Hf, R₁ is selected from a linear alkyl group having 2 to 6 carbon atoms and a branched alkyl group having 3 to 6 carbon atoms, R₂ is a linear alkyl group having 1 to 3 carbon atoms, and R₁ and R₂ are different from each other.

A method for forming a Group 4 metal-containing thin film according to one example of the present disclosure includes a step of depositing a thin film on a substrate through a metal organic chemical vapor deposition (MOCVD) process or an atomic layer deposition (ALD) process using the organometallic compound represented by Formula 1 above as a precursor.

Detailed matters of other examples are included in the detailed description and drawings.

The organometallic compound according to one example of the present disclosure is present in a liquid state at room temperature, thereby having an advantage of facilitating storage and handling.

Further, the organometallic compound according to one example of the present disclosure has excellent volatility, thereby having an advantage of facilitating transfer and supply of the organometallic compound to the reaction chamber during thin film deposition.

Further, the organometallic compound according to one example of the present disclosure includes substituents asymmetrically disubstituted on the cyclopentadiene group, thereby having an advantage of excellent structural and thermal stability. Accordingly, when a thin film is deposited using this as a precursor, it is possible to obtain a Group 4 metal-containing thin film having uniform film quality while reducing a residue content since the ligand is easily removed without thermal decomposition.

Further, the organometallic compound according to one example of the present disclosure has an advantage of enabling a thin film to be stably deposited in a wide temperature range from a low temperature to a high temperature.

Effects according to the present disclosure are not limited by the contents exemplified above, and more various effects are included in the present disclosure.

### BRIEF DESCRIPTION OF THE DRAWINGS

FIG. 1 is a graph showing the results of nuclear magnetic resonance analysis (¹H NMR) of a compound according to Example 1.

FIG. 2 is a graph showing the results of thermogravimetric analysis (TGA) of a compound according to Example 1 and a compound according to Comparative Example 1.

FIG. 3 is photographs showing the results of evaluating thermal stabilities of a compound according to Example 1 and a compound according to Comparative Example 1.

FIG. 4 is a graph showing the results of analyzing residue contents depending on heating temperatures of a compound according to Example 1 and a compound according to Comparative Example 1.

FIG. 5 is a graph showing the growth per cycle of thin films depending on temperatures during ALD using a compound according to Example 1 and a compound according to Comparative Example 1, respectively.

### DETAILED DESCRIPTION OF THE EMBODIMENT

Advantages and features of the present disclosure, and methods of achieving them, will become clear with reference to the examples described below in detail in conjunction with the accompanying drawings. However, the present disclosure is not limited to the examples disclosed below, but will be implemented in a variety of different forms, only these examples make the disclosure of the present disclosure complete, and are provided to completely inform the person who has common knowledge in the art to which the present disclosure pertains of the scope of the invention, and the present disclosure is only defined by the scope of the claims.

In describing the present disclosure, if it is determined that a detailed description of related known technologies may unnecessarily obscure the subject matter of the present disclosure, the detailed description will be omitted. When ‘includes’, ‘has’, ‘consists’, etc. mentioned in the present disclosure are used, other parts may be added unless ‘only’ is used. In the case where a component is expressed in the singular, the case including the plural is included unless specifically stated otherwise.

In interpreting the components, even if there is no separate explicit description, it is interpreted as including the error range.

Throughout the specification of the present application, the term “room temperature” means a temperature of 15° C. to 30° C.

Throughout the specification of the present application, a hydrogen atom of a compound may be substituted with one selected from light hydrogen, deuterium, and tritium that are isotopes.

Throughout the specification of the present application, unless otherwise stated, percentages are by weight.

An organometallic compound according to one example of the present application may be represented by Formula 1 below.

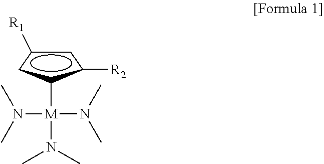

In Formula 1, M may be zirconium (Zr) or hafnium (Hf).

In Formula 1, R₁ may be selected from a linear alkyl group having 2 to 6 carbon atoms and a branched alkyl group having 3 to 6 carbon atoms, and R₂ may be a linear alkyl group having 1 to 3 carbon atoms. In this case, the ligand is easily removed in the deposition process for forming a Group 4 metal-containing thin film so that a high-quality thin film may be obtained according as the residue content is reduced.

In the organometallic compound according to Formula 1, substituent R₁ is substituted at the ortho position of cyclopentadiene, and substituent R₂ is substituted at the para position based on carbon bonded to the metal element (M) in the cyclopentadiene structure. In addition, R₁ and R₂ are different from each other in Formula 1. Accordingly, the organometallic compound according to Formula 1 has an asymmetric structure in which the positions and types of substituents bonded to cyclopentadiene are different.

As the substituents R₁ and R₂ are asymmetrically substituted in the cyclopentadiene group as described above, the compound of Formula 1 exhibits characteristics of a high vapor pressure even at low temperatures. During MOCVD or ALD, the organometallic compound is vaporized and supplied to the reaction chamber. The organometallic compound represented by Formula 1 has excellent volatility as substituents bonded to cyclopentadiene are asymmetrically substituted, and accordingly, there is an advantage in that the organometallic compound is easily transferred and supplied to the reaction chamber during the deposition process.

Further, the asymmetric disubstituted cyclopentadiene ligand may more easily supply electrons to the metal atom by substituents, and thus, the organometallic compound of Formula 1 has an advantage of being structurally and thermally stable. When the organometallic compound deteriorates in structural and thermal stability, its viscosity increases in the process of vaporizing it in an evaporator. Accordingly, there may be a difficulty in transferring and supplying a gaseous organometallic compound to the reaction chamber, and the quality of the thin film may deteriorate. As described above, the organometallic compound represented by Formula 1 is structurally and thermally stable. Accordingly, in the process of vaporizing the organometallic compound in the evaporator for the purpose of the deposition process, it may be vaporized without being decomposed by heat.

Further, since the organometallic compound of Formula 1 has excellent thermal stability, it has an advantage of enabling deposition to be performed in a wide temperature range from low temperatures to high temperatures. In addition, the amount of residue generated as the ligand is removed during the deposition process may be reduced. Accordingly, a high-quality Group 4 metal-containing thin film with low residue content and high density may be formed.

Further, the organometallic compound of Formula 1 is present in a liquid state at room temperature. Accordingly, there is an advantage of facilitating storage and handling.

Unlike the above-described description, when the substituents R₁ and R₂ are the same, and the positions where they are substituted form a symmetrical structure, the organometallic compound may not be present as a liquid at room temperature but may be solidified, or there may be a difficulty in vaporization of the organometallic compound. In this case, there are problems in that the thickness or physical properties of the thin film formed through the deposition process are not uniform, and the quality of the thin film deteriorates.

There are no problems with cyclopentadiene substituents. However, in the case of having a symmetrical ligand in the existing precursor structure, there has been a case in which the organometallic compound sometimes became a solid or did not vaporize well.

For example, R₁ in Formula 1 may be selected from a linear alkyl group having 3 to 6 carbon atoms and a branched alkyl group having 3 to 6 carbon atoms, and R₂ may be a methyl group. In this case, it is possible to obtain a high-quality Group 4 metal-containing thin film which is excellent in both structural stability and thermal stability, and has low residue content and high density when the thin film is formed by the deposition process using the organometallic compound of Formula 1 as a precursor.

More specifically, the organometallic compound represented by Formula 1 may be an organic zirconium compound represented by Formula 2 below or an organic hafnium compound represented by Formula 3 below.

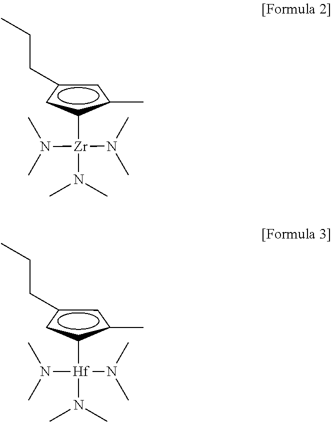

Zirconium (Zr) and hafnium (Hf) are Group 4 metal elements and have excellent physical properties, but zirconium has advantages of being stably supplied and having low price compared to hafnium. Accordingly, the organic zirconium compound represented by Formula 2 has advantages having lower preparation cost and easier preparation than those of the organic hafnium compound represented by Formula 3.

The organometallic compound according to one example of the present disclosure is excellent in both structural stability and thermal stability. Accordingly, the organometallic compound according to one example of the present disclosure may be used as a precursor for depositing a Group 4 metal-containing thin film.

Hereinafter, a method for forming a Group 4 metal-containing thin film according to one example of the present disclosure will be described.

The method for forming a Group 4 metal-containing thin film according to one example of the present disclosure includes a step of depositing a thin film on a substrate through a deposition process using the organometallic compound represented by Formula 1 as a precursor. If necessary, the organometallic compound may be dissolved in a solvent and used.

For example, the deposition process may be a metal organic chemical vapor deposition (MOCVD) process or an atomic layer deposition (ALD) process.

For example, the deposition process may be carried out in a temperature range of 200° C. to 400° C. In this case, a high-quality Group 4 metal-containing thin film may be formed by removing the ligand while minimizing the residue content.

The step of depositing the thin film includes a step of transferring the organometallic compound represented by Formula 1 to a reaction chamber on which a substrate is mounted.

For example, the organometallic compound of Formula 1 may be supplied onto the substrate by a bubbling method, a vapor phase mass flow controller method, a direct gas injection (DGI) method, a direct liquid injection (DLI) method, a liquid transfer method in which it is dissolved in an organic solvent and transferred, or the like, but is not limited thereto.

If necessary, the organometallic compound may be supplied together with a carrier gas or a dilution gas. The carrier gas has no reactivity with the organometallic compound, and is lighter than the organometallic compound to easily transfer the vaporized organometallic compound to the substrate. The dilution gas does not cause side reactions due to its non-reactivity with the organometallic compound, and the reaction such as the growth per cycle of the thin film may be easily controlled by controlling the flow rate thereof. For example, each of the carrier gas and dilution gas may be one or more selected from argon (Ar), nitrogen (N₂), helium (He), and hydrogen (H₂).

For example, the organometallic compound is mixed with a carrier gas or dilution gas containing one or more selected from argon (Ar), nitrogen (N₂), helium (He), and hydrogen (H₂) so that it may be transferred onto the substrate by a bubbling method or a direct gas injection method.

The step of depositing the thin film may include a step of supplying a reaction gas.

For example, when a Group 4 metal oxide thin film is to be manufactured, a reaction gas containing oxygen may be supplied. For example, the reaction gas containing oxygen may include one or more selected from water vapor (H₂O), oxygen (O₂), ozone (O₃), and hydrogen peroxide (H₂O₂). Such a reaction gas reacts with an organometallic compound in the thin film deposition process to allow a Group 4 metal oxide thin film to be formed.

As another example, when a Group 4 metal nitride thin film is to be manufactured, a reaction gas containing nitrogen may be supplied. For example, the reaction gas containing nitrogen may include one or more selected from ammonia (NH₃), hydrazine (N₂H₄), nitrous oxide (N₂O), and nitrogen (N₂). Such a reaction gas reacts with an organometallic compound in the thin film deposition process to allow a Group 4 metal nitride thin film to be formed.

When thermal energy, plasma, electric bias, etc. are applied to the substrate after the organometallic compound of Formula 1 is supplied onto a substrate, ligands included in the organometallic compound are decomposed to form a Group 4 metal-containing thin film on the substrate.

A step of removing an organometallic compound remaining unreacted by purging an inert gas such as argon (Ar), nitrogen (N₂), helium (He), and/or hydrogen (H₂) into the reaction chamber when a thin film having a desired thickness is formed may be included.

The organometallic compound according to one example of the present disclosure includes asymmetric disubstituted substituents in a cyclopentadiene structure, and thus has excellent structural stability and thermal stability. Accordingly, a Group 4 metal-containing thin film formed through an MOCVD process or an ALD process using the organometallic compound as a precursor has excellent step coverage, thereby advantages of having high density while having uniform film thickness.

Further, the organometallic compound is present in a liquid state at room temperature so that it is easy to handle, is not thermally decomposed, and is easily volatilized, thereby having an advantage that it is easily transferred and supplied to a chamber for thin film deposition.

Further, the ligand of the organometallic compound is easily removed during the thin film deposition process, thereby having an advantage of greatly reducing the content of the residue in the thin film.

Further, since the organometallic compound has excellent thermal stability, there is an advantage in that a thin film may be stably formed in a wide deposition temperature range from low temperatures to high temperatures when forming the thin film.

Furthermore, the Group 4 metal-containing thin film obtained according to one example of the present disclosure has excellent film quality, and thus, may be used for a gate dielectric film, a capacitor dielectric film, or the like of a semiconductor device.

Hereinafter, the organometallic compound according to the present disclosure and the Group 4 metal-containing thin film formed using the same will be described in more detail through the following Examples. However, this is only presented to help understanding of the present disclosure, and the present disclosure is not limited to the following Examples.

### Example 1

1. Preparation of [ⁿPrMe(η-C₅H₅)]

After 40 g (0.25 mol) of methylcyclopentadiene dimer was put into a flame-dried 250 mL Schlenk flask, it was heated to 180° and stirred. 30 g (0.37 mol, 1 equivalent) of methylcyclopentadiene obtained from the flask was put into a flame-dried 1 L Schlenk flask. After 48.35 g (0.39 mol, 1.05 equivalent) of 1-bromopropane and 350 ml of tetrahydrofuran were put into the flask, the mixture was stirred. After 37.78 g (0.39 mol, 1.05 equivalent) of sodium tert-butoxide dissolved in tetrahydrofuran was added dropwise to the flask at 0° C. or lower, the dissolved solution was stirred at room temperature for 12 hours. After the reaction solution was filtered, 21.47 g (yield of 47%) of a clear liquid compound represented by [ⁿPrMe(η-C₅H₅)] was obtained by removing the solvent and performing distillation under reduced pressure.

Unless otherwise specified, in the formula, ⁿPr means a linear propyl group and Me means a methyl group.

2. Preparation of [(ⁿPrMe(η-C₅H₅))Zr(NMe₂)₃]

After 44.8 g (0.17 mol, 1 equivalent) of tetrakis(dimethylamino)zirconium [Zr(NMe₂)₄] and 300 ml of n-hexane were put into a flame-dried 500 mL Schlenk flask, the mixture was stirred at room temperature. After 21.45 g (0.18 mol, 1.05 equivalent) of n-propylmethylcyclopentadiene (ⁿPrMe(η-C₅H₅)) was added dropwise to the flask at 0° C. or lower, the mixture was stirred at room temperature for 12 hours. After the reaction solution was filtered, 43.53 g (yield of 75%) of a pale yellow liquid compound was obtained by removing the solvent and performing distillation under reduced pressure. The compound thus prepared is a compound [(ⁿPrMe(η-C₅H₅))Zr(NMe₂)₃] represented by Formula 2.

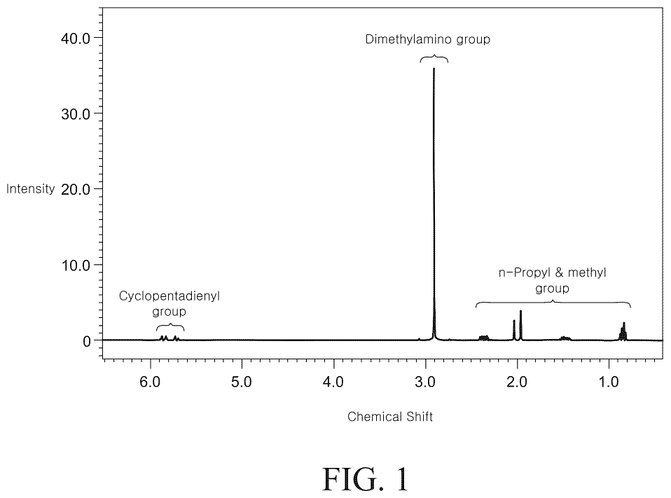

Nuclear magnetic resonance analysis (¹H NMR) (using C₆D₆ as a solvent) was performed in order to check the synthesis of the compound, and the results according to this are attached in FIG. 1. Synthesis of the compound represented by Formula 2 was confirmed based on the nuclear magnetic resonance analysis results shown in FIG. 1.

3. Preparation of Zirconium Oxide Thin Film

A zirconium oxide thin film was deposited on a silicon substrate by atomic layer deposition using the compound [(ⁿPrMe(η-C₅H₅))Zr(NMe₂)₃] prepared above as a precursor. A showerhead-type thermal ALD reactor was used as an atomic layer deposition machine, ozone gas was used as a reaction gas, and argon gas was used as a purge gas and a carrier gas. A zirconium precursor compound contained in the canister was vaporized using a vaporizer heated to 160° C. through a liquid flow meter (LFM), and supplied at a flow rate of 0.02 to 0.04 g/min. A zirconium precursor compound vaporized into a vapor phase in the vaporizer was supplied to the reaction chamber together with 600 to 2,000 sccm of an argon carrier gas. Thereafter, a step 1 of supplying the zirconium precursor compound for 5 seconds, a step 2 of supplying argon gas for 10 seconds to remove an unreacted residual zirconium precursor compound, a step 3 of supplying 600 sccm of ozone gas for 5 seconds in order to react the zirconium precursor compound adsorbed on the substrate surface, and a step 4 of supplying argon gas for 10 seconds to remove the remaining residue were performed, and the thin film deposition was carried out by performing steps 1 to 4 as one cycle.

### Comparative Example 1

A zirconium oxide thin film was deposited on a silicon substrate in the same manner and conditions as in Example 1 above by obtaining [CpZr(NMe)₃] as a zirconium precursor and using it as a precursor. In the above-mentioned formula, Cp means a cyclopentadiene group.

### Experimental Example 1

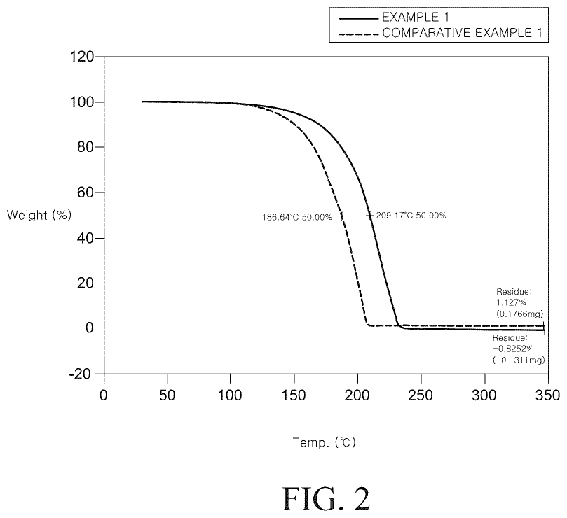

Thermogravimetric analysis (TGA) was performed on the compound of Formula 2 prepared in Example 1 above and [CpZr(NMe)₃] of Comparative Example 1. Thermogravimetric analysis was performed in a glove box purged with inert purified nitrogen, and the test material was measured while raising the temperature from room temperature to 350° C. at a rate of 10° C./min. The results according to this are shown in FIG. 2. FIG. 2 is a graph showing the results of thermogravimetric analysis (TGA) of a compound according to Example 1 and a compound according to Comparative Example 1.

Referring to FIG. 2, it may be confirmed that the compound according to Example 1 has a half-life (T_{1/2}) of about 209° C., the compound according to Comparative Example 1 has a half-life of about 186° C., and the compound according to Example 1 starts thermal decomposition at a temperature higher than that of the compound according to Comparative Example 1. It may be seen from this that the compound according to Example 1 has excellent thermal stability compared to the compound according to Comparative Example 1. In addition, it may be confirmed that the compound according to Example 1 has a smaller residue content than the compound according to Comparative Example 1, and from this, Example 1 may be predicted to be more excellent in the film quality as the ligand is well removed during thin film deposition.

### Experimental Example 2

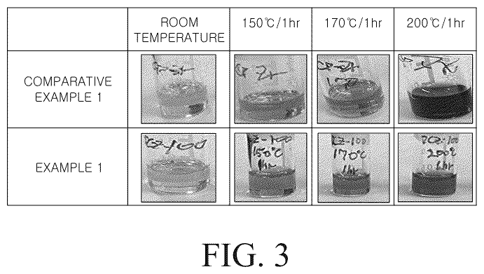

Thermal stabilities of the compound represented by Formula 2 prepared according to Example 1 and the compound [CpZr(NMe)₃] according to Comparative Example 1 were evaluated. Thermal stabilities were evaluated by putting each of the compound according to Example 1 and the compound according to Comparative Example 1 into 4 containers, keeping one sample at room temperature, heating the remaining 3 samples at 150° C., 170° C., and 200° C. respectively for 1 hour, and then visually observing the state of the solution. The results according to this are shown in FIG. 3. FIG. 3 is photographs showing the results of evaluating thermal stabilities of a compound according to Example 1 and a compound according to Comparative Example 1.

Referring to FIG. 3, it may be confirmed that each of the compounds according to Example 1 and Comparative Example 1 has a transparent yellow color at room temperature. It may be confirmed that the color darkens as the heating temperature increases, and it may be confirmed that, when heated at 200° C., the compound according to Example 1 exhibits a light brown color, but the compound according to Comparative Example 1 exhibits a dark brown color, and discoloration is severe in Comparative Example 1 compared to Example 1. It may be seen from this that the compound according to Example 1 has excellent thermal stability compared to the compound according to Comparative Example 1.

### Experimental Example 3

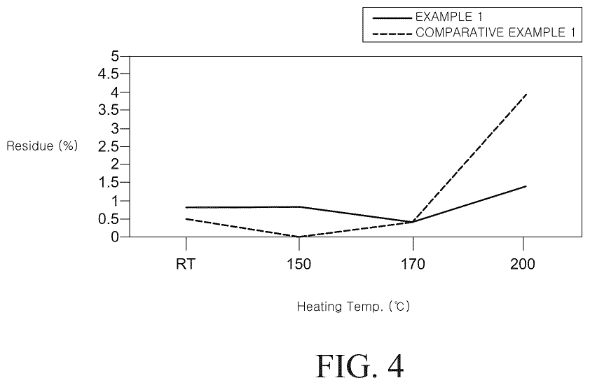

After thermal stabilities were evaluated with the naked eye in Experimental Example 2, thermogravimetric analysis was performed on each of 8 samples. Thermogravimetric analysis was performed under the same conditions as in Example 1. The results according to this are shown in Table 1 and FIG. 4. FIG. 4 is a graph showing the results of analyzing residue contents depending on heating temperatures of a compound according to Example 1 and a compound according to Comparative Example 1. In Table 1 and FIG. 4, RT means room temperature.

TABLE 1

| | | T_{1/2} (° C.) | Residue content (%) |
|---|---|---|---|
| Example 1 | RT | 213 | 0.8 |
| | 150° C., 1 hr | 216 | 0.8 |
| | 170° C., 1 hr | 204 | 0.4 |
| | 200° C., 1 hr | 214 | 1.4 |
| Comparative | RT | 189 | 0.5 |
| Example 1 | 150° C., 1 hr | 189 | 0.0 |
| | 170° C., 1 hr | 186 | 0.4 |
| | 200° C., 1 hr | 191 | 3.9 |

Referring to Table 1 and FIG. 4 together, it may be confirmed that the compound according to Example 1 has a high half-life compared to Comparative Example 1 under all temperature conditions, and it may be confirmed that the residue content at a high temperature (200° C.) is small compared to Comparative Example 1. It may be seen from this that the compound according to Example 1 is thermally stable, and is remarkably low in the production of impurities due to side reactions at high temperatures compared to Comparative Example 1.

### Experimental Example 4

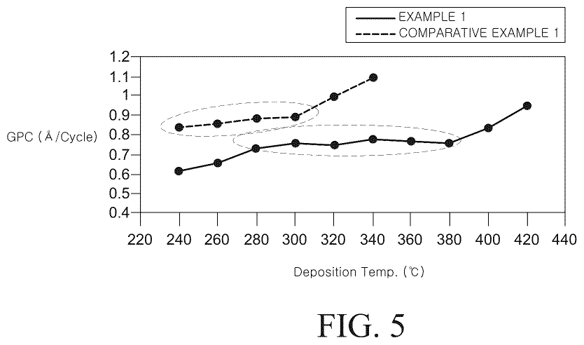

When performing an ALD process using each of the compound represented by Formula 2 according to Example 1 and the compound [CpZr(NMe)₃] according to Comparative Example 1 as a precursor, the growth per cycle (GPC) of the thin film according to the temperature (Deposition Temp.) was analyzed. The ALD process was performed in the manner mentioned previously in Example 1 and Comparative Example 1. The results according to this are shown in FIG. 5. FIG. 5 is a graph showing the grow per cycle of thin films depending on temperatures during ALD using a compound according to Example 1 and a compound according to Comparative Example 1, respectively.

Referring to FIG. 5, when ALD is performed using the compound of Formula 2 according to Example 1 as a precursor, an ALD temperature window in which there is little difference in the grow per cycle of the thin film in the temperature range of 280° C. to 380° C. is observed. The ALD temperature window is a temperature range in which ALD stably occurs, and in a temperature range outside the ALD temperature window, ALD is not stable, and physical properties of the thin film greatly deteriorate. That is, when the compound according to Example 1 is used as a precursor, a high-quality thin film with uniform thickness and physical properties of the zirconium oxide thin film is formed in a wide temperature range of 280° C. to 380° C. Meanwhile, when ALD is performed using the compound according to Comparative Example 1 as a precursor, it may be confirmed that the ALD temperature window ranges from 240° C. to 300° C., and the ALD temperature window has a narrow range compared to Example 1. It may be seen from this that, when the compound according to Comparative Example 1 is used as a precursor, it is impossible to form a high-quality zirconium oxide thin film through ALD at a high temperature of 300° C. or higher.

Summarizing the above Experimental Examples, the compound according to one example of the present disclosure has excellent structural stability and thermal stability, and when a deposition process is performed using it as a precursor, a high-quality Group 4 metal-containing thin film having uniform film thickness and quality and low residue content may be obtained.

Organometallic compounds according to various examples of the present disclosure and a method for forming a Group 4 metal-containing thin film may be described as follows.

An organometallic compound according to one example of the present disclosure is represented by Formula 1 below.

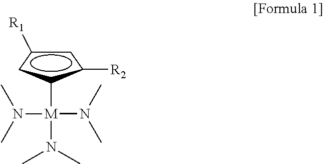

In Formula 1, M is Zr or Hf, R₁ is selected from a linear alkyl group having 2 to 6 carbon atoms and a branched alkyl group having 3 to 6 carbon atoms, R₂ is a linear alkyl group having 1 to 3 carbon atoms, and R₁ and R₂ are different from each other.

According to another feature of the present disclosure, R₁ in Formula 1 may be selected from a linear alkyl group having 3 to 6 carbon atoms and a branched alkyl group having 3 to 6 carbon atoms, and R₂ may be a methyl group.

According to yet another feature of the present disclosure, the organometallic compound may be represented by Formula 2 below.

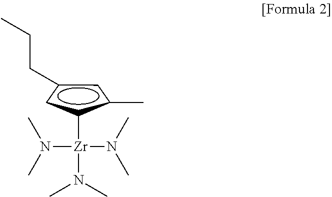

According to still another feature of the present disclosure, the organometallic compound may be represented by Formula 3 below.

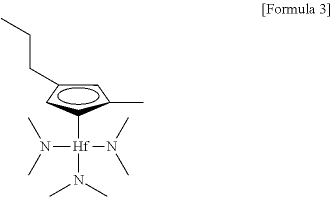

According to yet still another feature of the present disclosure, the organometallic compound may be a liquid at room temperature.

A method for forming a Group 4 metal-containing thin film according to one example of the present disclosure includes a step of depositing a thin film on a substrate through a metal organic chemical vapor deposition (MOCVD) process or an atomic layer deposition (ALD) process using the organometallic compound as a precursor.

According to a further feature of the present disclosure, the deposition process may be performed in a temperature range of 200° C. to 400° C.

According to a still further feature of the present disclosure, the step of depositing a thin film may include a step of moving the organometallic compound to the substrate through one method selected from a bubbling method, a vapor phase mass flow controller (MFC) method, a direct gas injection (DGI) method, a direct liquid injection (DLI) method, and an organic solution supply method in which the organometallic compound is dissolved in an organic solvent and moved.

According to a yet further feature of the present disclosure, the organometallic compound may be moved onto the substrate by the bubbling method or the direct gas injection method together with a carrier gas, and the carrier gas may include one or more selected from argon (Ar), nitrogen (N₂), helium (He), and hydrogen (H₂).

According to a yet still further feature of the present disclosure, the step of depositing a thin film may further include a step of supplying one or more reaction gases selected from water vapor (H₂O), oxygen (O₂), ozone (O₃), and hydrogen peroxide (H₂O₂).

According to another feature of the present disclosure, the step of depositing a thin film may further include a step of supplying one or more reaction gases selected from ammonia (NH₃), hydrazine (N₂H₄), nitrous oxide (N₂O), and nitrogen (N₂).

Although the present disclosure has been described in detail through Examples above, the present disclosure is not necessarily limited to these Examples, and may be variously modified and implemented within the scope that does not deviate from the technical idea of the present disclosure. Therefore, the Examples disclosed in the present disclosure are not intended to limit the technical idea of the present disclosure, but to explain it, and the scope of the technical idea of the present disclosure is not limited by these Examples. Therefore, it should be understood that the Examples described above are illustrative in all respects and not restrictive. The protection scope of the present disclosure should be construed according to the claims below, and all technical ideas within the range equivalent thereto should be construed as being included in the scope of rights of the present disclosure.

What is claimed is:

1. An organometallic compound represented by Formula 1 below. 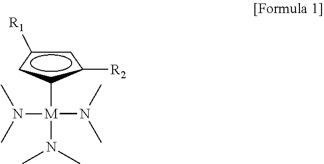
In Formula 1,
M is Zr or Hf,
R₁ is selected from a linear alkyl group having 2 to 6 carbon atoms and a branched alkyl group having 3 to 6 carbon atoms, R₂ is a linear alkyl group having 1 to 3 carbon atoms, and R₁ and R₂ are different from each other.

2. The organometallic compound of claim 1, wherein R₁ in Formula 1 is selected from a linear alkyl group having 3 to 6 carbon atoms and a branched alkyl group having 3 to 6 carbon atoms, and R₂ is a methyl group.

3. The organometallic compound of claim 1, wherein the organometallic compound is represented by Formula 2 below.

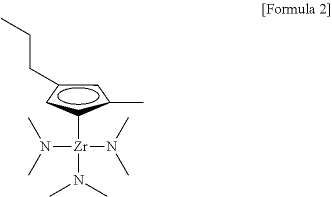

4. The organometallic compound of claim 1, wherein the organometallic compound is represented by Formula 3 below.

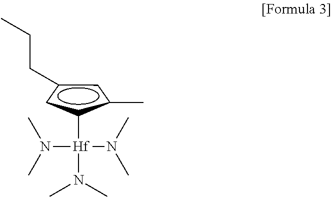

5. The organometallic compound of claim 1, wherein the organometallic compound is a liquid at room temperature.

6. A method for forming a Group 4 metal-containing thin film, the method comprising a step of depositing a thin film on a substrate through a metal organic chemical vapor deposition (MOCVD) process or an atomic layer deposition (ALD) process using the organometallic compound of any one of claims 1 to 5 as a precursor.

7. The method of claim 6, wherein the deposition process is carried out in a temperature range of 200° C. to 400° C.

8. The method of claim 6, wherein the step of depositing a thin film includes a step of moving the organometallic compound to the substrate through one method selected from a bubbling method, a vapor phase mass flow controller (MFC) method, a direct gas injection (DGI) method, a direct liquid injection (DLI) method, and an organic solution supply method in which the organometallic compound is dissolved in an organic solvent and moved.

9. The method of claim 8, wherein the organometallic compound is moved onto the substrate by the bubbling method or the direct gas injection method together with a carrier gas, and the carrier gas includes one or more selected from argon (Ar), nitrogen (N₂), helium (He), and hydrogen (H₂).

10. The method of claim 6, wherein the step of depositing a thin film further includes a step of supplying one or more reaction gases selected from water vapor (H₂O), oxygen (O₂), ozone (O₃), and hydrogen peroxide (H₂O₂).

11. The method of claim 6, wherein the step of depositing a thin film further includes a step of supplying one or more reaction gases selected from ammonia (NH₃), hydrazine (N₂H₄), nitrous oxide (N₂O), and nitrogen (N₂).
